(19) United States
(12) Patent Application Publication
(10) Pub. No.: US 2026/0314285 A1
(43) Pub. Date: Oct. 8, 2026

(54) METHOD AND CARRIER SUBSTRATE FOR PRODUCING A COMPONENT COMPRISING ALUMINUM NITRIDE

(71) Applicant: JENOPTIK Optical Systems GmbH, Jena (DE)

(72) Inventors: Meik PANITZ, Jena (DE); Sabine ZYBELL, Jena (DE); Daniel GRIMM, Jena (DE); Martin TILKE, Jena (DE); Lutz RAUPACH, Jena (DE)

(73) Assignee: JENOPTIK Optical Systems GmbH, Jena (DE)

(21) Appl. No.: 19/481,247

(22) PCT Filed: Apr. 30, 2024
(86) PCT No.: PCT/EP2024/061852

§ 371 Date: Nov. 4, 2025

(30) Foreign Application Priority Data
May 5, 2023 (DE) 10 2023 111 715.7

(51) Int. Cl. H10P 50/64; H10P 50/24

(52) U.S. Cl. CPC H10P 50/642; H10P 50/24

(57) ABSTRACT

A method for producing a semiconductor component with at least one exposed membrane portion. A semiconductor material is provided having a carrier substrate with a passivation layer. A membrane layer is applied to the passivation layer, the membrane layer being formed from an aluminum nitride material in which a ratio of aluminum to nitrogen is within a range between 1.05 to 1.4. A protective layer is applied to the membrane layer. A part of the carrier substrate is removed using a wet-chemical process, in order to obtain a region of the passivation layer that is devoid of the substrate. A section of the membrane layer is exposed in the region that is devoid of the substrate by a first dry etching step for etching the passivation layer and a second dry etching step for etching the protective layer, in order to obtain the exposed membrane section.

The present invention relates to a method and to an apparatus for producing a component having on either side an exposed membrane portion composed of aluminum nitride with an aluminum excess, in accordance with the main claims.

KR 10-2021-0084381 A discloses a membrane composed of AlN, BN or quartz. KR 10-2018-0057813 A discloses a phase shift mask having a metal nitride layer composed for example of AlN. KR 10-2018-0029384 A discloses a further AlN membrane, and also a component comprising such a membrane.

DE 10 2011 005 249 A1 discloses an apparatus for converting mechanical energy into electrical energy, and a method for producing it. Described in this context is the production of a curved piezoelectric membrane.

JP 2013-160706A discloses a flow detector on a semiconductor substrate with a bared sensor region.

Set out in DE 10 2022 111 943 B3 are a method and a carrier substrate for producing a semiconductor component, wherein a membrane ply is formed from AlN.

For modern semiconductor components, high flexibility is often a prerequisite in terms of the physical properties, so that in the case of optical semiconductor components, for example, a beam of light can be guided effectively. A semiconductor component in the context of this invention may be understood as a component which is produced on a semiconductor substrate as carrier substrate, for example a semiconductor wafer, for example a silicon wafer. This may be a mechanical and/or optical component, in which the semiconductor properties of the substrate may possibly be irrelevant to the function. It may be a mechanical component, an optical component, or a component for the NIR region, the visible region, the UV region, the EUV region or the x-ray region of electromagnetic waves. Such semiconductor components may be produced using typical techniques in the semiconductor industry. A problem here, however, is that certain advantageous physical properties are to some degree possessed by types of material that are difficult to process. For example, a material may have a good, desirable physical property such as high mechanical robustness, high thermal conductivity, a desired electrical resistance, a desired elasticity modulus and/or a particular refractive index that can interact particularly favorably at an interface with the other material, for example air. Outstanding properties for such applications as a thin membrane may be possessed by aluminum nitride. Advantageous physical properties may be established through a nonstoichiometric composition of the aluminum nitride. At the same time, however, this very material may also be water-soluble or hydrolyzable, for example, so that certain process steps used in conventional semiconductor production methods cannot be used to process such a material.

Proceeding from this statement of the problem, a means of enabling improved processing and hence the production of a component comprising a thin nonstoichiometric aluminum nitride membrane having improved properties is now presented.

This object is achieved by the subjects of the main claims.

The approach presented here presents a method for producing a semiconductor component having at least one exposed membrane portion, wherein the method comprises the following steps:
a) providing a semiconductor material which comprises a carrier substrate provided with a passivation layer;
b) applying a membrane ply to the passivation layer, wherein the membrane ply is formed from an aluminum nitride material in which a ratio of aluminum to nitrogen is in the range between 1.05 to 1.4,
c) applying a protective layer to the membrane ply, wherein the membrane ply is covered, on a side opposite the passivation layer, by the protective layer;
d) removing a part of the carrier substrate using a wet-chemical method, to give a substrate-free region of the passivation layer; and
e) exposing a portion of the membrane ply in the substrate-free region by means of a first dry etching step for etching the passivation layer and a second dry etching step for etching the protective layer, to give the exposed membrane portion.

Steps a-e may advantageously be carried out in the order stated. The exposed membrane portion may be exposed on both sides, by the passivation layer and the protective layer having been removed completely in this portion. The etching of the protective layer may entail removal of said layer completely from the entire semiconductor material or else only in regions, more particularly in the regions in which the exposed membrane portions are provided.

Step e may advantageously be preceded by a cleaning step performed with an aqueous detergent, more particularly a wet-chemical cleaning method. The cleaning step may in particular take place after step d.

The exposed membrane portion may, but does not have to, have a perforated embodiment.

A carrier substrate may mean, for example, a conventional substrate, composed for example of silicon. It may be a monocrystalline silicon wafer. This carrier substrate may be provided with a passivation layer which comprises a silicon nitride, for example, or consists of such a material.

A membrane ply may mean a layer that has a particularly advantageous property, for example with regard to its optical and/or mechanical characteristics, but that comprises a material or consists of a nonstoichiometric aluminum nitride material which is alterable in its structure and/or composition by water, more particularly hydrolyzable. For example, a mechanical structure of this material may degrade when the material comes into contact with water, or a layer of this material breaks up or tears. Hydrolyzing may mean intercalation of water molecules, in which case this material can then precipitate out or crystallize again in the event of evaporation or vaporization of the water. In the case of hydrolyzing, it is alternatively possible for the material to be broken down chemically by contact with water. Aluminum nitride may be hydrolyzable, for example, close to the surface, with formation of ammonia. Hence aluminum nitride, as a compact material or as a thick layer, may be fairly resistant toward water exposure, yet may be rapidly destroyed by hydrolysis when in the form of a thin layer. More particularly, thin layers of nonstoichiometric aluminum nitride, especially those with aluminum excess, may be particularly susceptible to water exposure. On the other hand, an aluminum excess may favor permanent tensile stress of the membrane, which is desirable for some applications.

The present approach is based on the realization that specifically the use of an aluminum nitride material for the membrane ply, wherein the ratio of aluminum to nitrogen is in the range from 1.05 to 1.40, particularly advantageously in the range from 1.10 to 1.30, has very positive properties with regard on the one hand to the optical diffraction and on the other hand to mechanical stability of a membrane ply produced from such a material. Furthermore, a desired mechanical tensile strain can be reproducibly established. To obtain a flat, free-standing AlN membrane, the layer tension of the membrane may be established for example at a tensile strain of 100 MPa to 1000 MPa. The ratio of aluminum to nitrogen may be assumed as the atomic ratio of aluminum atoms to nitrogen atoms, which may also be referred to as the amount-of-substance ratio. By virtue of the ratio presented here, a distinct increase is achievable in the design flexibility of a component, which on the one hand can be adapted in particular for different optical applications and on the other hand also enables use for robust applications, as the membrane ply has a high mechanical stability. Additionally enabled thereby is a significantly improved handling of the carrier substrate or semiconductor material when processing, through a capacity for reduced failure rates due to mechanical damage to the components produced with the approach presented here.

The solution presented here may bring about an improvement in mechanical and optical properties, in producibility and in long-term stability of the component. Moreover, the service life of the membrane ply, especially when in the form of a free-standing membrane, can be prolonged, as degradation due to subsidence in the tensile strain of the membrane can be prevented or retarded by comparison with known membrane plies composed of stoichiometric AlN.

A protective layer in the present context may mean a cover of the membrane ply. In this case, the protective layer and the passivation layer, which favorably consist of a water-insoluble material or one which is not alterable in its structure and/or composition by water, or contain this material, may ensure that the membrane ply is sealed in a fluid-tight manner from an environment of the semiconductor component (up to, for example, lateral edges of the wafer). In this way it is possible to ensure that the membrane ply is not damaged on processing or structuring of regions of the carrier substrate or of the semiconductor component, which would destroy the semiconductor component to be produced. A wet-chemical method may mean one or more process steps of a wet etching method or a wet cleaning method in which a liquid etchant and/or detergent is used to introduce structures into the semiconductor material or to clean a surface of the semiconductor material. A dry etching method may mean a process step in which the semiconductor material is structured using a physical or mechanical ablation method or using a gaseous etchant. Moreover, it is possible but not obligatory for the first and second dry etching steps to be performed with an identical dry etching method and/or to be conducted in one operating step. Likewise advantageous are two successively executed dry etching steps on one side each of the semiconductor component. It is also possible for the order of the steps of providing, removing and exposing to take place advantageously in the sequence specified, in which case the first and second dry etching steps are executed as component steps of the exposing step and may also be performed in any order.

The approach proposed here offers the advantage of ensuring, by the use of the different etching or cleaning methods in different processing stages, that the membrane ply, which is composed of a sensitive to an etching or cleaning material used in one of the process steps, remains very largely undamaged.

There is advantage to an embodiment of the approach proposed here which has an additional step of
f) applying a cover ply to the protective layer, wherein the protective layer with the cover ply forms a layer stack as protective ply, wherein a material of the protective layer differs from a material of the cover ply.

The cover ply may advantageously be applied after the application of the protective layer in accordance with step c) and before the exposure in accordance with step e), particularly advantageously before the removal of a part of the carrier substrate in accordance with step d).

In particular, the material of the cover ply may comprise a reflective material and/or a metal. The method may further comprise a step to be performed before the second dry etching step, more particularly before the step of removing a part of the carrier substrate (step d):
g) structuring the protective ply, wherein the protective layer is exposed at least in places by removal of the cover ply, more particularly using an auxiliary mask by means of an etching method used in the case of the first or second dry etching method, or by means of a further etching method.

Such an embodiment offers the advantage of making it possible, by virtue of the different materials of the layers of the protective ply, to undertake structuring of this protective ply in a very flexible manner, so that, even in a later process step, flexible configuration of the exposed membrane ply can be achieved. Through the use of a metal for the cover ply, electrical conductor tracks can be made on the component surface. By virtue of the use of a reflective material for the cover ply, it is also possible, for example, to realize desired optical properties of the finished semiconductor component and/or to attach reflective markings for the positioning of the semiconductor component or the wafer on which a plurality of semiconductor components may be located.

To form the free-standing membrane it is possible, in the structuring step, to remove a portion of the carrier substrate in the structured region, to give a substrate-free region. Such an embodiment of the approach proposed here offers the option of using known efficient processing steps to prepare the semiconductor material or the semiconductor component in such a way that in the subsequent exposure step, the dry etching method can be used exclusively. In this way it is possible by means of the prior processing of the semiconductor material to prevent any surface of the membrane ply which is then possibly already exposed from being damaged by an etchant or detergent which is too aggressive for the material of the membrane ply.

A particularly advantageous embodiment of the approach proposed here is one in which the structuring step is executed in such a way that the membrane ply is sealed by the passivation layer and at least part of the protective layer against an etchant or detergent in the wet-chemical process. Such an embodiment offers the advantage of reliably protecting the membrane ply against the etchant in the wet-chemical process and hence preventing damage to the membrane ply.

In a further embodiment of the approach proposed here, in the exposure step, the passivation layer and at least part of the protective layer can be removed by the dry etching method. Such an embodiment of the approach proposed here offers the advantage that the dry etching method is already employed in a first exposure of the membrane ply, and this allows the membrane ply to be protected as well as possible and structured efficiently.

Semiconductor components of a particularly intricate configuration which is efficient for an end use may be produced when the membrane ply itself is also not only exposed but also structured. For this purpose, for example, passage holes may be introduced into the membrane ply, for example in order to enable implementation of an attenuator of electromagnetic radiation or an optical structure, for example a stop structure, in the membrane ply in the exposed membrane portion. Such a stop structure may comprise passage holes having a greater diameter than a design light wavelength of the component, in order to form conventional stops. In a particularly favorable embodiment, it is therefore possible in the exposure step to at least partly remove the membrane ply so as to obtain a perforated exposed membrane portion, more particularly wherein a structured region of the protective layer and/or a resist mask applied to the protective layer and/or to the cover ply can be used as an etch mask. Such a perforation may have perforation holes having a greater diameter than a design wavelength of the component, in order to form conventional stops. It is also possible for perforation holes to be provided that have a smaller diameter than a design light wavelength of the component, in order thus to produce evanescent electromagnetic waves or to act as a shortpass filter. The perforated membrane portion may constitute a diffraction grating for electromagnetic radiation. It should be pointed out that electromagnetic radiation in the context of this invention may mean x-ray radiation, EUV/XUV radiation, UV radiation, visible light and infrared light. The optical function of the component (at a design wavelength) may be provided in each of the stated wavelength ranges. A tensile strain in the membrane may prevent unwanted curving of the membrane. Furthermore, components of these kinds may be used as ultrasonic detectors. In that case, deflection of the membrane may be evaluated by capacitive or optical means, for example. For this application, the permanently maintained tensile strain of the membrane may be particularly relevant.

Furthermore, such components with passage openings in the membrane may be employed as effective pressure reducers for gases. In that case, the chosen size of the openings may be small enough to permit Knudsen flow or molecular flow. This makes it possible, for example, to meter a small amount of a trace gas reproducibly into a gas stream. A pressure reducer of this kind may also be used as a test leakage for testing high-vacuum installations.

Additionally, according to a further embodiment of the approach presented here, in the structuring and exposing step, the membrane ply, the carrier substrate, the protective layer, a masking layer and the passivation layer can be removed, in a passage region laterally adjacent to the structured region, in such a way that an opening is formed into which no portion of the membrane ply projects. Such an embodiment of the approach proposed here offers the advantage that the method presented here can also be used to structure other regions of the semiconductor material in which no exposed portions of the membrane ply are required. In this way, the structuring of the semiconductor material or of the semiconductor component can be undertaken in a compact manner with few work steps, which allows production costs and production time to be reduced.

A particularly favorable embodiment, moreover, is one in which, in the structuring step, a holding material is applied to a portion of the passivation layer that has been exposed in the passage region, wherein, in the exposure step, after removal of the carrier substrate and the passivation layer in the passage region, the holding material is removed to form the opening. A holding material may mean, for example, a polymer material, for example a photoresist, that can also be used for introducing structures into different layers of the semiconductor material. The holding material can also be applied together with a further material to a surface of the semiconductor material or the semiconductor component. The use of such a semiconductor material, which is applied directly to the passivation layer for example, can prevent flakes or fragments of a layer to be removed from falling into the processing space in an uncontrolled manner and causing faults in a subsequent step. Instead, such fragments, which may arise from continuous reduction of the thickness of the layer to be removed, can be stabilized or cohesively held by the holding material, such that residue-free removal or dissolution of these fragments becomes possible. The holding material may advantageously be applied here to the side of the passivation layer remote from the substrate, in the region of the intended passage region.

It is also possible in a very flexible manner to use an embodiment of the approach proposed here in which, in the exposure step, the opening is formed in such a way that it has a greater diameter than an opening in the exposed region of membrane ply. Such an embodiment offers the advantage of enabling introduction of structures of different dimensions into the semiconductor material by a uniform method or process, such that the realization of desired functions in a semiconductor element can be implemented efficiently.

A semiconductor component having particularly advantageous properties can be realized especially when, in the providing step, a semiconductor material is provided in which the passivation layer and/or a masking layer at least partly comprises a silicon nitride and/or in which the membrane ply at least partly comprises an aluminum nitride, a germanium oxide and/or an aluminum oxide, and/or wherein the cover ply comprises a metal, especially chromium, and/or the protective layer comprises a silicon and/or silicon nitride. In this way, it is possible to realize semiconductor components of very advantageous configuration specifically for optical applications.

In an embodiment that can be used particularly advantageously for the realization of the different steps of the approach proposed here, the wet-chemical method conducted in the structuring step is a wet etching method using potassium hydroxide or tetramethylammonium hydroxide as etchant, and/or a wet-chemical cleaning method, and/or, in the exposure step, a dry etching method is conducted using a physical dry etching method, a chemical dry etching method and/or a physicochemical dry etching method.

The thickness of the membrane ply here may be between 5 nm and 1000 nm, advantageously between 10 nm and 500 nm, particularly advantageously between 20 nm and 200 nm and very particularly advantageously between 40 nm and 150 nm. Such an embodiment offers the advantage, through the low thickness relative to the prior art, of being able to realize very favorable electromagnetic properties of the membrane ply and of the component comprising the membrane ply. For example, the refractive index of the free-standing membrane in the shortwave region can be close to 1 and the absorption coefficient can be >0.03. At the same time, it is nevertheless possible by virtue of this thickness, when selecting the stated stoichiometric ratio (also through the occurrence of the tensions), to realize a sufficiently stable membrane ply. The membrane ply thickness provided advantageously for this purpose may be at least 10 nm, advantageously at least 20 nm, likewise advantageously at least 40 nm. In this way, the use possibilities of a component thus produced can be significantly extended, as the design of the component can be expanded into very different technical fields and different wavelength ranges.

In one particularly advantageous embodiment of the approach proposed here, in the step of applying the membrane ply, a plasma process is performed, especially for cleaning the applied membrane ply; more particularly, this plasma process uses a hydrogen plasma and/or an oxygen plasma. Such an embodiment offers the advantage, through the plasma process, of obtaining a cleaned membrane ply which on the one hand exhibits high-quality optical properties and on the other hand acquires mechanical stresses which have very advantageous consequences for the stability of such a component.

In a further favorable embodiment of the approach proposed here, in the step of applying the membrane ply, nitrogen is supplied into a processing chamber in which the membrane ply is applied to the passivation layer; more particularly, the amount of nitrogen supplied in the processing chamber is lower than the amount of hydrogen required to produce a stoichiometric membrane ply. An advantage of such an embodiment is that the regulated supply of nitrogen allows the ratio of aluminum to nitrogen to be established very precisely during the deposition or formation of the membrane ply, so that an embodiment of this kind enables high flexibility when realizing desired material parameter combinations in the production of the membrane ply.

The lateral extent of the exposed region of the membrane may advantageously be between 50 μm and 5000 μm, particularly advantageously between 100 μm and 500 μm.

The membranes may be perforated, for example with a hole pattern in which the lateral hole separations are between 50 nm and 5000 nm, advantageously 100 nm to 1000 nm. The membranes may be used, for example, for absorption and/or diffraction of electromagnetic rays.

In another favorable embodiment of the approach presented here, the substrate-free region of the semiconductor material has edges whose normal has an angle of less than 60°, especially 54.7°, to a surface normal of the carrier substrate, more particularly wherein the semiconductor material is monocrystalline and the edges are formed by etch-resistant crystal planes. For example, it is possible to use a silicon wafer with a {100} surface. If the edges are formed by {111} and equivalent crystal faces, the angle may be 54.74°.

These variants of methods may be implemented, for example, in software or hardware or in a mixed form of software and hardware, for example as control commands in a control device or an apparatus.

The approach presented here also provides an apparatus designed to perform, actuate or implement the steps of a variant of a method presented here in corresponding devices. This execution variant of the invention in the form of an apparatus can also achieve the object underlying the invention in a rapid and efficient manner.

For this purpose, the apparatus may have at least one computation unit for processing signals or data, at least one storage unit for storing signals or data, at least one interface to a sensor or an actuator for importing sensor signals from the sensor or for exporting data signals or control signals to the actuator, and/or at least one communication interface for importing or exporting data embedded in a communication protocol. The computation unit may be, for example, a signal processor, a microcontroller or the like, where the storage unit may be a flash memory, an EEPROM or a magnetic storage unit. The communication interface may be designed for wireless and/or line-bound import or export of data, and a communication interface that can import or export line-bound data is able to import these data for example electrically or optically from a corresponding data transmission line or export them into a corresponding data transmission line.

An apparatus in the present context may mean an electrical device that processes sensor signals and gives out control signals and/or data signals depending thereon. The apparatus may have an interface that may be in the form of hardware and/or software. In hardware form, the interfaces may, for example, be part of what is called a system ASIC, which includes a wide variety of different functions of the apparatus. However, it is also possible that the interfaces are dedicated integrated circuits or at least partly consist of discrete components. In software form, the interfaces may be software modules that are present in a microcontroller alongside other software modules, for example.

Also advantageous is a computer program product or computer program comprising program code, which may be stored on a machine-readable carrier or storage medium, such as a semiconductor memory, a hard drive or an optical storage medium, and which is used for performance, implementation and/or actuation of the steps of the method according to any of the above-described embodiments, especially when the program product or program is executed on a computer or an apparatus.

A further aspect of the invention is a carrier substrate for producing at least one component having at least one exposed membrane portion, having a passivation layer disposed on a first side, wherein a membrane ply is disposed on the passivation layer, wherein the membrane ply is formed of an aluminum nitride material in which the ratio of aluminum to nitrogen is in the range between 1.05 to 1.4, wherein the membrane ply is covered on a side opposite the passivation layer by a protective layer, wherein the protective layer comprises silicon and/or silicon nitride, wherein the protective layer with a cover ply forms a layer stack as protective ply, wherein a material of the protective layer differs from a material of the cover ply and the cover ply comprises a metal, and an etch mask for wet etching of the substrate has also been applied on a second side, opposite the first side, of the carrier substrate. This carrier substrate may be used advantageously for producing the component.

Working examples of the approach presented here are shown in the drawings and elucidated in detail in the description that follows. The figures show:

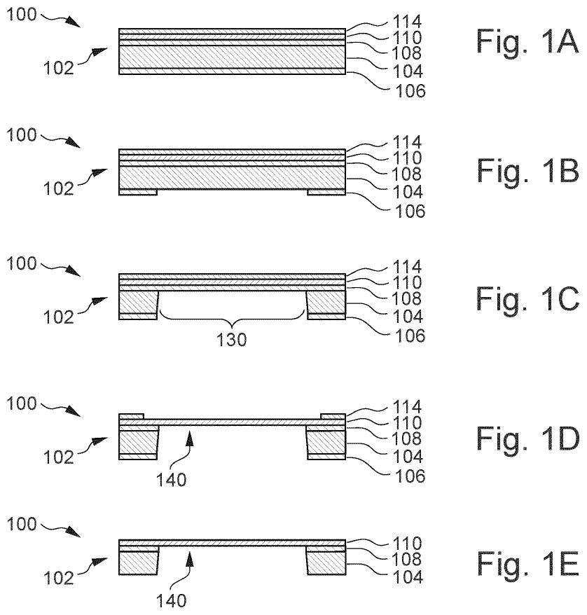

FIG. 1A to 1E multiple part-diagrams that each show a cross section of a semiconductor component to be produced according to a first working example, in different process steps;

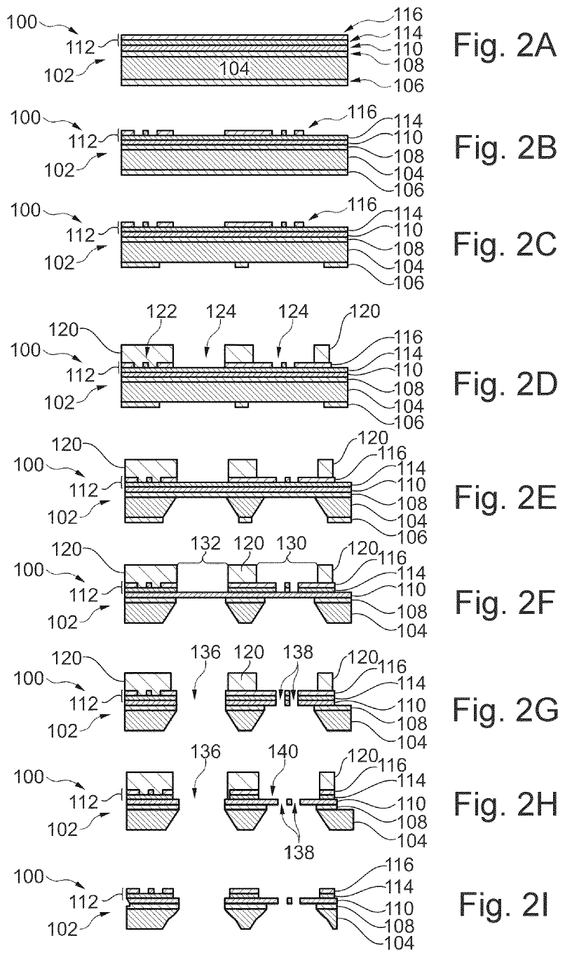

FIG. 2A to 21 multiple part-diagrams that each show a cross section of a semiconductor component to be produced according to a second working example, in different process steps;

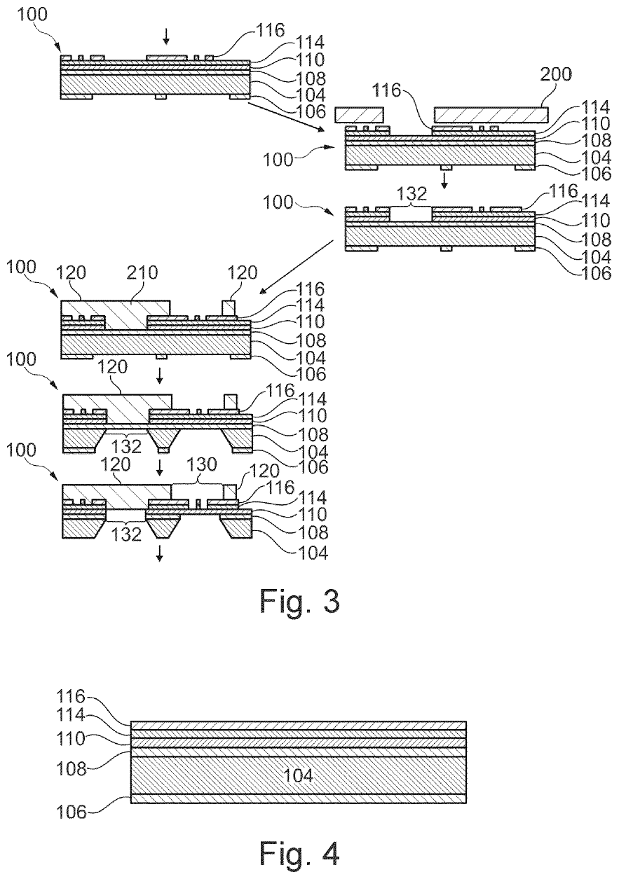

FIG. 3 multiple part-diagrams that each show a cross section of a semiconductor component to be produced according to a third working example, in different process steps;

FIG. 4 a schematic cross section of the layer stack used, as starting material for the semiconductor component;

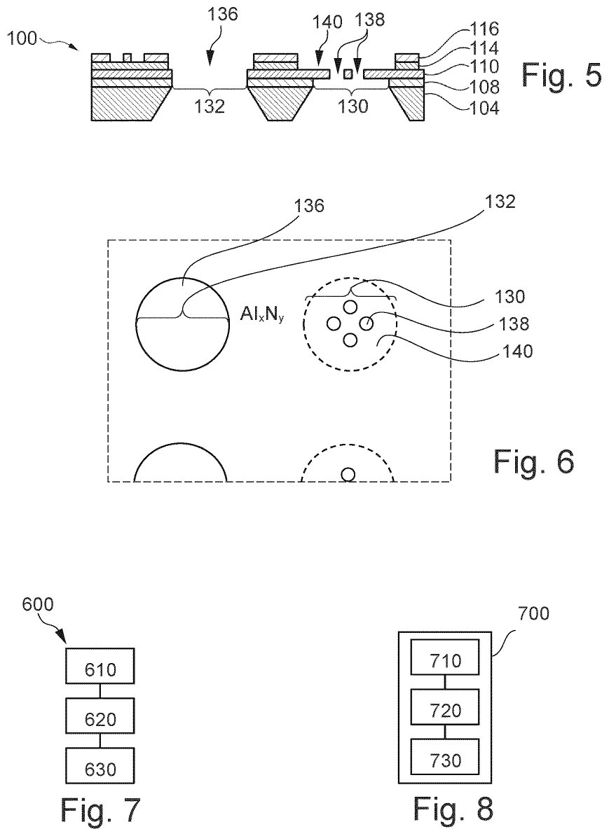

FIG. 5 a cross section of a structured wafer with a semiconductor component;

FIG. 6 a plan view of a structured aluminum nitride membrane that has been produced with the proposed process sequence;

FIG. 7 a flow diagram of a working example of a method for producing a semiconductor component; and

FIG. 8 a block diagram of a working example of an apparatus for producing a semiconductor component.

In the description of favorable working examples of the present invention that follows, identical or similar reference numerals are used for the elements that are shown in the different figures and have similar effects, without a repeated description of these elements. FIG. 1 shows, in each of several part-diagrams reproduced as FIG. 1A to FIG. 1E, a cross section of a semiconductor component 100 to be produced according to a first working example, after different process steps.

FIG. 1A firstly shows a semiconductor material 102 in the form of a stack of multiple plies. This semiconductor material 102 comprises a carrier substrate 104 produced from silicon, for example, or comprising this material. The semiconductor substrate 104 further comprises a lower masking layer 106 and a passivation layer 108, each of which includes a silicon nitride (Si₃N₄), for example, or comprises this material. The masking layer 106 and the passivation layer 108 may be formed on the carrier substrate 104, for example, in the same production step. The membrane layer 110 is disposed on the passivation layer 108 and consists of aluminum nitride, in which the ratio of aluminum to nitrogen is in the range between 1.05 to 1.4. Disposed on the membrane ply 110 is a protective layer 114. This protective layer 114 may for example comprise silicon, silicon nitride, silicon oxide and/or a metal or may consist of one of the stated materials. It may alternatively be a resist layer, for example a photoresist.

In a first process step, according to this working example, the masking layer 106 is structured, for which it is possible for example to use a photoresist intended for exposure, and/or to use a wet etching method or alternatively a dry etching method.

FIG. 1B shows a cross-sectional diagram through a semiconductor component 100 in a state after execution of this method step.

In accordance with the first working example shown in FIG. 1, for the production of the semiconductor component 100, there is now a further method step of etching through the carrier substrate 104, using a wet etching method. Here, the use of the wet etching method enables flanks which descend obliquely in the carrier substrate through the openings of the masking layer 106, as made possible through the use of the wet etching method with corresponding alignment of the crystal structure of the carrier substrate 104. The formation of such flanks is very advantageous for optical applications, as is elucidated in detail hereinafter. The etching then proceeds as far as reverse-side exposure of the passivation layer 108, which serves as a stop layer for the wet etching method. In this way it is possible to avoid attack and hence damage or destruction of the water-soluble or water-sensitive membrane ply 110 by the wet etching method. In modifications of this working example that are not shown in figures, the flanks of the trenches may also be etched perpendicularly to the masking layer, and/or the masking layer may be under-etched.

FIG. 1C shows a cross-sectional diagram through a semiconductor component 100 in the state after execution of this method step. A substrate-free region 130 has been formed. In this region 130, the passivation layer 108 is exposed on one side-at the underside in the diagram. This state of the semiconductor component 100 is also the final state in this working example of production that can be worked by a step in the wet etching method. The subsequent steps take place using the dry etching method, to prevent damage or destruction of the membrane ply 110 by exposure to water molecules.

In a further step, the passivation layer 108 is removed in the substrate-free region 130 in a first component step, and the protective layer 114 is removed in a second component step. These two component steps may be performed in either order or else simultaneously. For this removal, a dry etching method is used. In this state, the use of a process step in a wet etching method would also attack and damage the membrane ply 110, and consequently, in accordance with the approach presented here, only a dry etching method can be used from this stage in the method onward for the processing of the semiconductor component 100. In the first working example shown, the passivation layer is removed only in the substrate-free region 130, since other places with substrate still intact are not accessible to the etching method. In the working example shown, the protective layer is removed only partially in a region which comprises the free-standing membrane. For this purpose, the protective layer can be etched selectively using an auxiliary mask (not shown in figures).

FIG. 1D shows a cross-sectional diagram through a semiconductor component 100 in the state after execution of this method step. The masking layer 106 may remain on the component, as shown, but need not do so. In the example shown, the protective layer 114 has been removed only partially, specifically in a region which has been chosen to be somewhat larger than the substrate-free region 130. In a modification not shown in figures, the protective layer 114 is removed in a region corresponding to the substrate-free region 130. In a further modification not shown in figures, the protective layer 114 is removed in a region which is smaller than the substrate-free region 130.

FIG. 1E shows a cross-sectional diagram through a semiconductor component 100 in a further modification of the first working example. Here, the protective layer has been removed completely. In a further modification of the first working example, in a subsequent step, there is removal of the masking layer 106 and optionally separation of the individual parts of the semiconductor component 100.

FIG. 2, in each of multiple part-diagrams reproduced as FIG. 2A to FIG. 21, shows a cross section of a semiconductor component 100 to be produced according to a second working example, after different process steps.

FIG. 2A firstly shows a semiconductor material 102 in the form of a stack of multiple plies. The semiconductor material 102 here comprises a carrier substrate 104 which is produced from silicon, for example, or comprises this material. The semiconductor substrate 104 further comprises a lower masking layer 106 and a passivation layer 108, each for example including a silicon nitride (Si₃N₄) or comprising this material. The masking layer 106 and the passivation layer 108 may be formed on the carrier substrate 104 in the same production step, for example. Disposed on the passivation layer 108 is the membrane ply 110, which consists of aluminum nitride for which a ratio of aluminum to nitrogen is in the range between 1.05 to 1.4. Disposed on the membrane ply 110 is a protective ply 112, comprising for example a protective layer 114 and a cover ply 116 disposed on the protective layer 114. This protective layer 114 may here include a silicon-based semiconductor material and be embodied as an etch stop layer. The cover ply 116 may for example comprise a reflective material and/or metal, chromium for example, or may consist of such a material.

In a first processing step, for example, there is structuring of the cover ply 116, for example of the reflective material, which may be carried out using, for example, a photoresist, which is exposed in accordance with a structure to be introduced into the cover ply 116. The cover ply 116 may be structured using a wet etching method or else, alternatively or additionally, a dry etching method.

FIG. 2B shows a cross-sectional diagram through a semiconductor component 100 in a state after implementation of the method steps specified above.

This is then followed, according to this working example, by structuring of the masking layer 106, for example likewise again using a photoresist for exposure and/or using a wet etching method or alternatively a dry etching method.

FIG. 2C shows a cross-sectional diagram through a semiconductor component 100 in a state after implementation of this method step.

In a further method step, structuring takes place using a photoresist as etching mask 120 in order to produce structures—for example, different grating types—in the semiconductor component 100. This enables the structuring of a substrate grating type 122 and on the other hand, in a further region, of a membrane grating 124.

FIG. 2D shows a cross-sectional diagram through a semiconductor component 100 in the state after implementation of this method step.

In accordance with the working example shown in FIG. 2 for the production of the semiconductor component 100, in a further method step, etching takes place through the carrier substrate 104 using a wet etching method. Here, the use of the wet etching method enables the formation, rather than trenches, of flanks which descend obliquely through the openings of the masking layer 106 in the carrier substrate, as is made possible through the use of the wet etching method with corresponding alignment of the crystal structure of the carrier substrate 104. For optical applications, the formation of flanks of this kind is very advantageous, as is elucidated in more detail below. Etching then takes place to the point of the reverse-side exposure of the passivation layer 108, which serves as a stop layer for the wet etching method. In this way it is possible to prevent the water-soluble or water-sensitive membrane ply 110 from being attacked, and thus damaged or destroyed, by the wet etching method.

FIG. 2E shows a cross-sectional diagram through a semiconductor component 100 in the state after implementation of this method step. At the same time, this state of the semiconductor component 100 is the final state in this working example of production that can be processed by a step of the wet etching method. The subsequent steps take place using the dry etching method, to prevent damage or destruction of the membrane ply 110 consisting of the water-soluble material or comprising this material.

In a subsequent step, it is possible to remove sacrificial layers which, in the present working example, are the exposed part of the passivation layer 108 from the reverse side of the carrier substrate 104, and also the part of the protective layer 114 not covered by the photoresist as etch mask 120 and/or by the cover ply 116. A dry etching method is used for this removal, since the membrane ply 110 is now exposed in a structured region 130 and in a passage region 132. The use of a process step of a wet etching method would also attack and damage the membrane ply 110 in this state, and so, according to the approach presented here, only a dry etching method may be used from this stage of the method onward for the processing of the semiconductor component 100.

FIG. 2F shows a cross-sectional diagram through a semiconductor component 100 in the state after implementation of this method step.

This may be followed, in a further method step, for example, by the removal of the membrane ply 110 in the passage region 132, such that a broad opening 136 through the semiconductor component 100 is created here. In addition, it is also possible in the structured region 130 to remove the membrane ply 110 exposed by the structured protective ply 112, specifically the structured protective layer 114 and the structured cover ply 116, which can be achieved, for example, by a dry etching method acting from above. In this way it is possible to structure the membrane ply 110 comprising the water-soluble or water-sensitive material in the manner desired. At the same time, it is also possible to realize very fine structures, for example holes 138, in the structured region 130 in the membrane ply 110, which makes it possible, for example, to embody the exposed membrane ply 110 to be produced subsequently as a movable element.

FIG. 2G shows a cross-sectional diagram through a semiconductor component 100 in the state after implementation of this method step.

Moreover, in a subsequent step, there is (dry) etching or removal of the region of the protective ply 112 that is not covered by the etch mask 120, i.e. of the uncovered part of the protective layer 114 and of the cover ply 116, which creates an exposed membrane portion 140 of the membrane ply 110 that for example also has fine structures such as passage holes 138. These passage holes 138 may also be distinctly smaller in their diameter than the opening 236 in the passage region 132.

FIG. 2H shows a cross-sectional diagram through a semiconductor component 100 in the state after implementation of this method step.

Finally, in a subsequent step, there is removal or (dry) etching of the etch mask 120 and optionally separation of the individual parts of the semiconductor component 100.

FIG. 21 shows a cross-sectional diagram through a semiconductor component 100 in the state after implementation of this method step.

The sub-figures of FIG. 2 thus show a scheme of the working example of a process sequence for production of free-standing, structured, nonstoichiometric aluminum nitride membranes using sacrificial protective layers and standard CMOS process steps. During all critical steps, the sensitive layers such as the membrane ply 110 are protected, which enables use of the wet and hence inexpensively implementable process steps.

With the approach presented here, it is thus possible to undertake the production of ultrathin, free-standing and structured membranes as membrane ply 110 from layer material which is sensitive in wet methods. In this way, it is nevertheless possible to efficiently realize the production of free-standing, ultrathin membranes, which generally entails many wet-chemical process steps of wet-chemical methods, such as lithography and wafer cleaning. For production of the free-standing membranes, the whole wafer is generally etched through by either dry or wet etching. While the dry etching methods such as DRIE (deep reactive ion etching) result in approximately vertical etch profiles through the wafer, wet etching methods may also result in oblique etch profiles in the etched groove. For optical applications, an oblique V-shaped side wall with wet etching is preferred in order thus to transmit electromagnetic radiation having high NA (numerical aperture) through a membrane without shadowing at the side walls of the wafer hole. If the membrane is used for fluidic functions, oblique side walls may have a nozzle or diffuser effect. But the use of wet etching methods with known technologies is, however, difficult or impossible when the membrane is to be formed from aluminum nitride. In the approach presented here, by contrast, a process sequence is presented that enables the production of virtually any free-standing membrane material. Additionally described is a method for producing structured membranes.

The production of free-standing membranes is a widely used technology for MEMS products or optical sensors, for example. Normally, robust materials such as SiN or metals are used as membrane material or material for the membrane ply 110. Depending on the application, however, the use of aluminum nitride is also desirable. However, at least in the case of thin layers, this material is hydrolyzable on exposure to water, and so a wet process step is not a direct possibility. Similarly, cleaning processes with the water-based cleaning chemicals typically used are not possible. With the method presented here, a desired component can be conveniently produced by wet-chemical means and can also have oblique etched substrate edges. A core concept of the invention are various sacrificial layers, protecting the sensitive layer of the membrane ply 110 from the wet environment. With this approach, it is possible to structure the membranes from nonstoichiometric aluminum nitride and also to apply in places a suitable reflective material for optical or ultrasonic sensor purposes. There are no restrictions on the precision of structuring apart from the resolution limit of the lithographic and etch tooling used. Here we show a minimum structure size<200 nm, which is within the resolution limit of the tooling.

The process proposed is described with reference to the processing stages of the semiconductor component that are shown in the sub-figures of FIG. 2. It comprises various standard process steps, for example coating, lithography, cleaning, wet and dry etching. The use of the process route proposed more wet cleaning steps can be performed, which improves the quality of the surface defects overall. In particular, it is actually possible to utilize the critical step of wet etching at least partly for the production of the components. An important aspect of the proposal presented here is the use of protective layers beneath (silicon nitride) and above the wet-sensitive layers during all wet process steps. These protective layers are ultimately etched away. The layer stack is chosen such that individual layers can be selectively etched without etching the other masking and/or protective layers. A further advantage of the approach or layer stack proposed is the possibility of adjusting the optical reflection capacity via the chosen materials and/or layer thicknesses. The introduction of the protective layer offers, for example, the option the introduction of the protective layer the option of bringing the reflection capacity virtually to zero for green light, for example, or of achieving maximum reflection capacity solely by varying the layer thickness.

In the process sequence proposed, the step between the processing stages shown in FIGS. 1F and 1G is a challenge. On etching through the last free-standing layer in order to open large holes as in the region of the passage opening 136, this layer is gradually thinned. If the remaining layer is too thin (~a few nanometers) to remain intact, the membrane, or the membrane ply 110 here, breaks before the etching operation has ended and rolls up to form glittery material. These shreds, which may consist of the wet-sensitive material, act as an unwanted masking layer in the subsequent processes. For that reason, a further-optimized process sequence has been developed in order to avoid this glittery material which might form due to the large openings.

FIG. 3 shows, in each of several part-diagrams, a cross section of a semiconductor component 100 to be produced according to a third working example, in different process steps. Proceeding from the processing state of the semiconductor component 100 shown in FIG. 2C, in a first intermediate step shown on the right, a shadow mask 200 is first used, which is used in a dry etching step for removal of the protective layer 114 in the passage region 132 by a dry etching method. In this way, the membrane ply 110 is exposed in the passage region 132. In a subsequent process step, the exposed membrane ply 110 is removed by a wet etching method or a dry etching method. This is then followed again by the procedure according to the diagram in FIG. 2D, except that the etch mask 120 is now additionally applied to the now exposed upper passivation layer 108 as well. In the subsequent steps, specifically in the transition from the processing states between the semiconductor components 100 depicted in FIGS. 2F and 2G, it is thus ensured that the upper passivation layer 108 now cannot break up into flakes (and nor can the membrane ply 110 already removed previously in the passage region 132), which can then act as erroneous optical masking.

FIG. 3 thus shows an optimized scheme for avoidance of glittery material consisting of material of the membrane ply. Two new process steps are included to selectively etch the layers in the regions of the large membrane openings 136, i.e. the passage region 132. All other process steps are the same or very similar to the previous process sequence in FIG. 2.

Two additional process steps (shown on the right-hand side in FIG. 3) serve for selective removal of the wet-sensitive nonstoichiometric aluminum nitride layer (membrane ply) 110 at the large openings. It is possible to use various etching methods. In the process scheme, we use a shadow mask by way of example, in order to open the buffer layer. All other processes correspond, for example, essentially to the sequence described above in FIG. 2. The sole difference is the use of a slightly adapted photomask in the step that leads to the semiconductor component according to FIG. 2D, in order to keep the large openings through the photoresist as etch mask 120 closed. This improved process sequence makes it possible to replace the critical step of etching through the free-standing wet-sensitive layer by process steps in which the etching takes place against a thick (free-standing) photoresist 120. In this way, it is possible to avoid occurrence of glittery material or flakes in the course of processing, consisting, for example, of broken ultrathin material.

FIG. 4 shows a schematic cross section-a working example of a carrier substrate (104) for producing at least one component (100) having at least one exposed membrane portion. Disposed on a first side of the carrier substrate (104) is a passivation layer (108). Disposed on the passivation layer (108) is a membrane ply (110), with the membrane ply (110) being formed of an aluminum nitride material for which a ratio of aluminum to nitrogen is in the range between 1.05 to 1.4. On a side opposite the passivation layer (108), the membrane ply (110) is covered by a protective layer (114). The protective layer (114) comprises silicon and/or silicon nitride. The protective layer (114) with a cover ply (116) forms a layer stack as protective ply (112), with a material of the protective layer (114) differing from a material of the cover ply (116). The cover ply (116) comprises a metal. Applied on a second side, opposite the first side, of the carrier substrate is an etch mask (106) for the wet etching of the substrate.

In one advantageous specific embodiment of the stated working example, the masking layer 106 and the passivation layer 108 may be designed, for example, as an etch stop layer. They may each comprise, for example, a silicon nitride layer 100 nm thick. In a further advantageous specific embodiment of the stated working example, the membrane ply 110 may have a thickness for example of 50 nm to 150 nm. In a further advantageous specific embodiment of the stated working example, the protective layer 114 may have a thickness for example of 20 nm to 200 nm. In a further advantageous specific embodiment of the stated working example, the protective layer 114 may be formed as stoichiometric silicon nitride Si3N4 or else nonstoichiometrically as any desired SixNy, advantageously with silicon excess. In a further advantageous specific embodiment of the stated working example, the cover ply 116 may be formed, for example, as a metal ply, composed for example of chromium, having a thickness for example of 20 nm to 200 nm.

FIG. 5 shows a cross section of a structured wafer with a semiconductor component 100, comprising reflective marking in the metal layer 116, large openings 136 that enable access to the reverse side of the wafer, and smaller passage holes 138 as a perforation of the free-standing nonstoichiometric aluminum nitride membrane 140.

The lateral dimensions of the markings structured in the metal layer 116 and of the structured holes 138 in the free-standing part 140 of the aluminum nitride membrane 110 are limited here merely by the resolution limit of the lithographic tooling in combination with the dry etching tools. It is possible to realize structures having lateral dimensions of ~100 nm. FIG. 6 shows a plan view of the kind typically observable in the SEM image (scanning electron microscope) of a structured free-standing AlN membrane 110 that has been produced with the process sequence proposed. The circles are holes 136 in the passage region 132 in the nonstoichiometric aluminum nitride membrane, which enable a clear pathway through the membrane 110 and the overall wafer 104. There are also substrate-free regions 130 in which the free-standing nonstoichiometric aluminum nitride membrane 140 is perforated with passage holes 138.

FIG. 7 shows a flow diagram of a method 600 for producing a semiconductor component with at least one exposed membrane portion, wherein the method includes a step 610 of providing a semiconductor material having a carrier substrate provided with a passivation layer, where a membrane ply is disposed on the passivation layer, said membrane ply being formed from an aluminum nitride material for which a ratio of aluminum to nitrogen is in the range between 1.05 to 1.4, and where the membrane ply is covered by a protective layer on an opposite side from the passivation layer. In addition, the method 600 comprises a step 620 of removing a part of the carrier substrate using a wet-chemical method, in order to obtain an exposed region of the passivation layer in a substrate-free region of the semiconductor material. Finally, the method 600 comprises a step 630 of exposing a portion of the membrane ply in the substrate-free region by means of a first dry etching step for etching of the passivation layer and a second dry etching step for etching of the protective layer, in order to obtain the exposed membrane portion.

FIG. 8 shows a block diagram of an apparatus 700 for production of a semiconductor component. The apparatus 700 comprises a unit 710 for provision of a semiconductor material having a carrier substrate provided with a passivation layer, wherein a membrane ply is disposed on the passivation layer, said membrane ply being formed from an aluminum nitride material for which a ratio of aluminum to nitrogen is in the range between 1.05 to 1.4, and where the membrane ply is covered by a protective ply on an opposite side from the passivation layer. The apparatus 700 further comprises a unit 720 for removing 620 a part of the carrier substrate 104 using a wet etching method, in order to obtain a substrate-free region of the semiconductor material. Finally, the apparatus 700 comprises a unit 730 for exposure of a portion of the membrane ply in the substrate-free region using a dry etching method in order to obtain an exposed membrane portion.

1. A method for producing a semiconductor component having at least one exposed membrane portion, wherein the method comprises the following steps:
a) providing a semiconductor material which comprises a carrier substrate provided with a passivation layer;
b) applying a membrane ply to the passivation layer wherein the membrane ply is formed from an aluminum nitride material in which a ratio of aluminum to nitrogen is in the range between 1.05 to 1.4;
c) applying a protective layer to the membrane ply wherein the membrane ply is covered, on a side opposite the passivation layer by the protective layer
d) removing a part of the carrier substrate using a wet-chemical method, to give a substrate-free region of the passivation layer and
e) exposing a portion of the membrane ply in the substrate-free region by means of a first dry etching step for etching the passivation layer and a second dry etching step for etching the protective layer, to give the exposed membrane portion

2. The method as claimed in claim 1, wherein the membrane ply has a thickness of between 10 nm and 500 nm.

3. The method as claimed in claim 1, further comprising a step to be performed before step e, more particularly before step d and after step c:
f) applying a cover ply to the protective layer wherein the protective layer with a cover ply forms a layer stack as protective ply wherein a material of the protective layer differs from a material of the cover ply more particularly wherein the material of the cover ply comprises a reflective material and/or a metal,
and further comprising a step to be performed before the second dry etching step, more particularly before the step of removing a part of the carrier substrate:
h) structuring the protective ply wherein the protective layer is exposed at least of an etching method used in the case of the first or second dry etching method, or by means of a further etching method.

4. The method as claimed in claim 3, wherein, in the structuring and exposing step in a passage region laterally adjacent to the substrate-free region the membrane ply the carrier substrate the protective layer and the passivation layer are removed in such a way that an opening passing through the semiconductor component is formed, more particularly an opening into which no portion of the membrane ply projects.

5. The method as claimed in claim 4, wherein contamination resulting from detachment of material residues of the passivation layer to be removed is avoided in the structuring step by applying a holding material to a portion of the passivation layer exposed in the passage region wherein the holding material is removed in the exposure step after removal of the carrier substrate and the passivation layer in the passage region in order to form the opening.

6. The method as claimed in claim 4, wherein, in the exposure step the opening is formed in such a way that it has a greater diameter than an opening in the exposed region of the membrane ply

7. The method as claimed in claim 1, wherein the wet-chemical method conducted in the structuring step is a wet etching method using potassium hydroxide or tetramethylammonium hydroxide as etchant and/or wherein the first and/or second dry etching step in the exposure step is conducted using a physical dry etching method, a chemical dry etching method and/or a physicochemical dry etching method.

8. The method as claimed in claim 1, wherein a plurality of semiconductor components are produced

9. The method as claimed in claim 1, wherein the step of exposing a portion of the membrane ply is preceded by at least one cleaning step with an aqueous detergent, more particularly a wet-chemical cleaning method.

10. The method as claimed in claim 1, wherein, in the exposure step the membrane ply is at least partly removed to give a perforated exposed membrane portion more particularly wherein a resist mask applied to the protective layer and/or to the cover ply is used as an etch mask.

11. The method as claimed in claim 1, wherein, in the providing step a semiconductor material is provided in which the passivation layer comprises a silicon nitride at least to some degree, and/or wherein the cover ply comprises a metal, more particularly aluminum or a transition metal, more particularly at least one of the transition metals titanium, nickel, chromium, tantalum, tungsten, platinum, and/or the protective layer comprises silicon and/or silicon oxide and/or silicon nitride.

12. The method as claimed in claim 1, wherein the substrate-free region of the semiconductor material has edges whose normal has an angle of less than 60°, especially 54.7°, to a surface normal of the carrier substrate, more particularly wherein the semiconductor material is monocrystalline and the edges are formed by etch-resistant crystal planes.

13. An apparatus set up to execute and/or actuate the steps of the method as claimed in claim 1 in corresponding units.

14. A computer program set up to execute and/or actuate the steps of the method as claimed in claim 1 when the computer program is executed on a computation unit.

15. A carrier substrate for producing at least one component having at least one exposed membrane portion, having a passivation layer disposed on a first side, wherein a membrane ply is disposed on the passivation layer wherein the membrane ply is formed of an aluminum nitride material in which a ratio of aluminum to nitrogen is in the range between 1.05 to 1.4, wherein the membrane ply is covered on a side opposite the passivation layer by a protective layer wherein the protective layer comprises silicon and/or silicon nitride, wherein the protective layer with a cover ply forms a layer stack as protective ply wherein a material of the protective layer differs from a material of the cover ply and the cover ply comprises a metal, and an etch mask for wet etching of the substrate has also been applied on a second side, opposite the first side, of the carrier substrate.
